(19) United States
(12) Patent Application Publication
(10) Pub. No.: US 2013/0146829 A1
(43) Pub. Date: Jun. 13, 2013

(54) RESISTIVE RANDOM ACCESS MEMORY DEVICES AND METHODS OF MANUFACTURING THE SAME

(71) Applicants: Kyung-min KIM, Seoul (KR); Young-bae KIM, Seoul (KR); Chang-jung KIM, Yongin-si (KR); Seung-ryul LEE, Seoul (KR); Chang-bum LEE, Seoul (KR); Man CHANG, Gwangju (KR)

(72) Inventors: Kyung-min KIM, Seoul (KR); Young-bae KIM, Seoul (KR); Chang-jung KIM, Yongin-si (KR); Seung-ryul LEE, Seoul (KR); Chang-bum LEE, Seoul (KR); Man CHANG, Gwangju (KR)

(73) Assignee: SAMSUNG ELECTRONICS CO., LTD., Suwon-si (KR)

(21) Appl. No.: 13/570,653

(22) Filed: Aug. 9, 2012

(30) Foreign Application Priority Data
Dec. 12, 2011 (KR) 1020110133053

(51) Int. Cl. H01L 47/00; H01L 21/02

(52) U.S. Cl. 257/2; 438/382; 257/E47.001; 257/E21.004

(57) ABSTRACT

Resistive random access memory (RRAM) devices, and methods of manufacturing the same, include a RRAM device having a switching device, and a storage node connected to the switching device, wherein the storage node includes a first electrode, a metal oxide layer, and a second electrode sequentially stacked. The metal oxide layer contains a semiconductor material element affecting resistance of the storage node.

### CROSS-REFERENCE TO RELATED APPLICATIONS

This application claims the benefit of priority from Korean Patent Application No. 10-2011-0133053, filed on Dec. 12, 2011, in the Korean Intellectual Property Office, the disclosure of which is incorporated herein by reference in its entirety.

### BACKGROUND

1. Field

Example embodiments relate to memory devices, and more particularly, to resistive random access memory (RRAM) devices and methods of manufacturing the same.

2. Description of the Related Art

A resistive random access memory (RRAM) is a type of non-volatile memory device. In a RRAM, a storage node includes a resistive body. Data is written in a RRAM device by using resistance changes of the resistive body.

It is necessary for a resistive body of a RRAM device to have reproducible resistance changes and durability against repeated resistance changes that conforms to commercialization standards.

Resistance change of the resistive body occurs as a voltage is applied thereto. Therefore, if a voltage required for changing resistance of the resistive body (i.e., operating voltage of a RRAM device) is high, it may be difficult to commercialize the RRAM device. The same applies to power consumption. If power required for operating a RRAM device exceeds a commercialization standard, it may be difficult to commercialize the RRAM device.

### SUMMARY

Example embodiments relate to memory devices, and more particularly, to resistive random access memory (RRAM) devices and methods of manufacturing the same.

Provided are resistive random access memory (RRAM) devices with enhanced operating characteristics.

Provided are methods of manufacturing the RRAM devices.

Additional aspects will be set forth in part in the description which follows and, in part, will be apparent from the description, or may be learned by practice of the presented embodiments.

According to example embodiments, a resistive random access memory (RRAM) device includes a switching device, and a storage node connected to the switching device, wherein the storage node includes a first electrode, a metal oxide layer, and a second electrode sequentially stacked, and the metal oxide layer contains a semiconductor material element affecting resistance of the storage node.

The metal oxide layer may include a base layer and an oxygen exchange layer sequentially stacked.

At least one of the base layer and the oxygen exchange layer may contain the semiconductor material element. The element may be distributed throughout the metal oxide layer, or in a portion of the metal oxide layer.

The RRAM device may further include a buffer layer between the first electrode and the metal oxide layer.

The base layer may be a nonstoichiometric TaOₓ layer.

The oxygen exchange layer may be a Ta₂O₅ layer.

The semiconductor material element may be silicon (Si).

According to example embodiments, a method of manufacturing a resistive random access memory (RRAM) device, the method includes forming a switching device on a substrate, and forming a storage node connected to the switching device by sequentially forming a first electrode, a metal oxide layer, and a second electrode, and a semiconductor material element affecting resistance of the storage node is added to the metal oxide layer.

The method may further include forming a buffer layer between the first electrode and the metal oxide layer.

The forming the metal oxide layer may further include forming a base layer on the first electrode, and forming an oxygen exchange layer on the base layer.

The semiconductor material element may be added to the metal oxide layer, when forming the metal oxide layer.

The semiconductor material element may be implanted to the metal oxide layer, after forming the metal oxide layer.

The semiconductor material element may be silicon (Si).

The semiconductor material element may be distributed throughout the metal oxide layer, or in a portion of the metal oxide layer.

The semiconductor material element may be added to at least one of the base layer and the oxygen exchange layer. The base layer may be a nonstoichiometric TaOx layer. The oxygen exchange layer may be a Ta₂O₅ layer.

### BRIEF DESCRIPTION OF THE DRAWINGS

These and/or other aspects will become apparent and more readily appreciated from the following description of the embodiments, taken in conjunction with the accompanying drawings of which:

FIG. 1 is a diagram showing a resistive random access memory (RRAM) device according to example embodiments;

FIG. 2 shows an example configuration of a storage node of FIG. 1;

FIG. 3 shows that silicon is distributed only in a portion of a first oxygen exchange layer in the storage node of FIG. 2;

FIG. 4 shows another example of the storage node of FIG. 1;

FIG. 5 shows that silicon is distributed only in a portion of a base layer in the storage node of FIG. 4;

FIG. 6 shows another example of the storage node of FIG. 1;

FIGS. 7 through 9 show experimental results of current-voltage characteristics of a storage node with the configuration in the related art and a storage node with the configuration according to example embodiments;

FIG. 10 shows changes of high resistance and low resistance respectively in the FIGS. 7 through 9;

FIG. 11 shows changes of reset voltage respectively in FIGS. 7 through 9; and

FIGS. 12 through 14 are sectional views showing a method of manufacturing a RRAM device according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

Expressions such as “at least one of,” when preceding a list of elements, modify the entire list of elements and do not modify the individual elements of the list.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to memory devices, and more particularly, to resistive random access memory (RRAM) devices and methods of manufacturing the same.

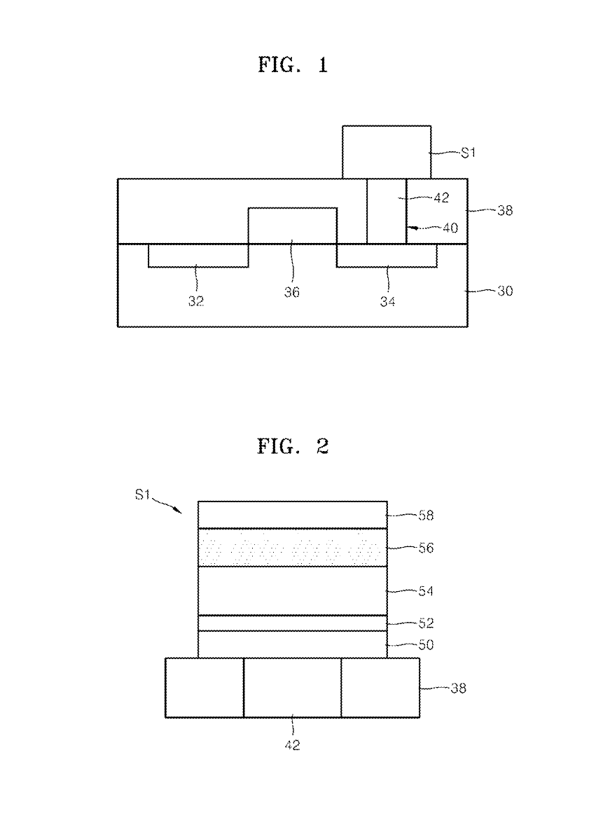

FIG. 1 is a diagram showing a resistive random access memory (RRAM) device according to example embodiments.

Referring to FIG. 1, first and second impurity regions 32 and 34 are arranged apart from each other on a substrate 30. The substrate 30 may be a semiconductor substrate and may be doped with an impurity. One of the first and second impurity regions 32 and 34 may be a source region, and the other one of the first and second impurity regions 32 and 34 may be a drain region. A gate stack 36 is arranged on a portion of the substrate 30 between the first and second impurity regions 32 and 34. The gate stack 36 may at least include a gate insulation layer (not shown) and a gate electrode (not shown) that are stacked in the order stated. The substrate 30, the first and second impurity regions 32 and 34, and the gate stack 36 may form a field effect transistor (referred to hereinafter as ‘transistor’). The transistor is merely a type of switching devices that may be arranged on the substrate 30. Instead of the transistor, other types of switching devices (e.g., a diode) may be arranged.

An interlayer insulation layer 38 is formed on the substrate 30 to cover the transistor. The interlayer insulation layer 38 includes a contact hole 40 via which exposes the second impurity region 34. The contact hole 40 is filled with a conductive plug 42. The conductive plug 42 is apart from the gate stack 36. The interlayer insulation layer 38 may be formed of a common insulation material used in a semiconductor device. A storage node S1 is arranged on the interlayer insulation layer 38 to cover the conductive plug 42. The storage node S1 contacts the conductive plug 42. The storage node S1 is a region to which data is written.

FIG. 2 shows an example configuration of the storage node of FIG. 1.

Referring to FIG. 2, a storage node S1 may include a first electrode 50, a buffer layer 52, a first base layer 54, a first oxygen exchange layer 56, and a second electrode 58 that are stacked in the order stated. The first electrode 50 may be a bottom electrode. The second electrode 58 may be a top electrode. The buffer layer 52 may be used as a buffer of a material layer formed thereon. Furthermore, when a material layer is formed on the buffer layer 52, the buffer layer 52 may prevent an impurity (e.g., oxygen) spreading from the material layer to the first electrode 50. The buffer layer 52 may be formed of Al₂O₃ or TiO₂, for example. The first base layer 54 may be a nonstoichiometric oxide layer. For example, the first base layer 54 may be a TaOₓ layer, where x may be from about 1.0 to about 2.5.

When a set operating voltage (referred to hereinafter as a first voltage) is applied to the storage node S1, oxygen ions may move from the first base layer 54 to the first oxygen exchange layer 56. As oxygen is supplied to the first oxygen exchange layer 56 as described above, an oxygen concentration at the interface between the first oxygen exchange layer 56 and the second electrode 58 rises. As the oxygen concentration rises, a Schottky barrier between the second electrode 58 and the first oxygen exchange layer 56 rises. Therefore, resistance of the storage node S1 rises to a first resistance. Accordingly, when resistance of the first oxygen exchange layer 56 is high, resistance of the storage node S1 also becomes high resistance. Although the first base layer 54 is connected to the first oxygen exchange layer 56 in series, the first base layer 54 barely affects resistance of the storage node S1 when resistance of the first oxygen exchange layer 56 is high resistance. Therefore, it may be considered that resistance of the storage node S1 is actually controlled by resistance of the first oxygen exchange layer 56.

The first voltage may be a reset voltage for changing resistance of the storage node S1 from low resistance to high resistance. When resistance of the storage node S1 is the first resistance, it may be considered that a first bit data (e.g., “1” (or “0”)) is written to the storage node S1.

Meanwhile, if an operating voltage opposite to the first voltage (referred to hereinafter as a second voltage) is applied to the storage node S1, oxygen ions move from the first oxygen exchange layer 56 to the first base layer 54. Therefore, oxygen concentration at the interface between the first oxygen exchange layer 56 and the second electrode 58 decreases to the concentration prior to the application of the first voltage. As a result, the Schottky barrier between the second electrode 58 and the first oxygen exchange layer 56 is lowered. Due to the application of the second voltage, resistance of the storage node S1 becomes a second resistance, which is lower than the first resistance. As described above, when resistance of the storage node S1 is low resistance, the resistance of the storage node S1 is actually controlled by the first base layer 54. When the resistance of the storage node S1 is the second resistance, it may be considered that a second bit data (e.g., “0” (or “1”)) is written to the storage node S1. When the second voltage is applied, a resistance of the storage node S1 becomes the resistance prior to the application of the first voltage. The second voltage may be a set voltage for changing resistance of the storage node S1 from the first resistance, (which is high resistance) to the second resistance (which is low resistance).

The first oxygen exchange layer 56 may be a metal oxide layer, for example. The metal oxide layer may be Ta₂O₅ layer, for example. However, the metal oxide layer may also be an oxide layer containing a metal atom other than Ta.

The metal oxide layer used as the first oxygen exchange layer 56 may contain an impurity as an element affecting reaction between the metal oxide layer and oxygen. Here, the impurity may be silicon (Si), for example. The impurity is distributed in the metal oxide layer without a chemical bond. Furthermore, the impurity may be uniformly distributed throughout the metal oxide layer or in a portion of the metal oxide layer (as discussed below).

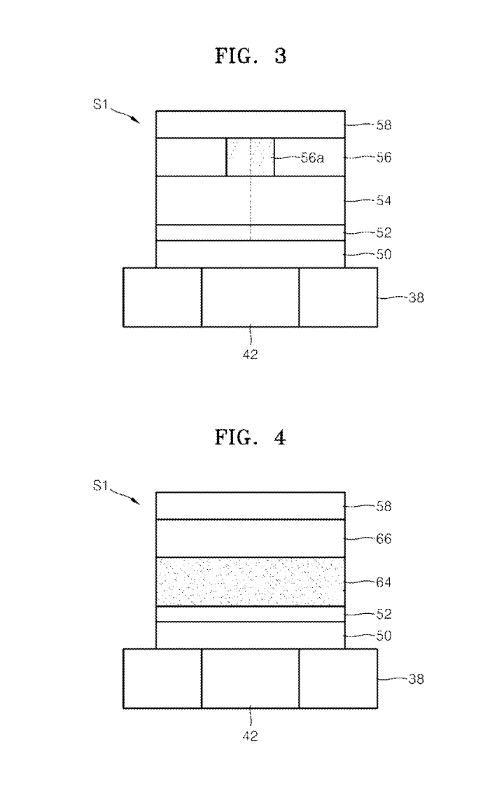

FIG. 3 shows that silicon is distributed only in a portion of a first oxygen exchange layer in the storage node of FIG. 2.

As shown in FIG. 3, the impurity may be distributed only in a portion 56a of the first oxygen exchange layer 56. In this case, a current path (dotted line) between the first electrode 50 and the second electrode 58 is formed via the portion 56a of the first oxygen exchange layer 56. Therefore, the current path between the first electrode 50 and the second electrode 58 is limited to a local area. In FIG. 3, oxygen moving from the first base layer 54 to the first oxygen exchange layer 56 move along the current path (dotted line) and reaches the interface between the portion 56a and the second electrode 58. Therefore, in FIG. 3, when the first voltage is applied, the oxygen concentration at the interface between the portion 56a of the first oxygen exchange layer 56 and the second electrode 58 rises, and thus the resistance of the storage node S1 becomes the first resistance. The impurity distributed in the portion 56a may affect the first resistance. For example, due to the silicon distribution, the first resistance may be higher as compared to a case where no silicon exists. In FIG. 3, a concentration of silicon distributed in the portion 56a of the first oxygen exchange layer 56 may be from 0 to about 0.2.

FIG. 4 shows another example of the storage node of FIG. 1.

Referring to FIG. 4, the storage node S1 may include the first electrode 50, the buffer layer 52, a second base layer 64, a second oxygen exchange layer 66, and the second electrode 58 that are stacked in the order stated. The second base layer 64 may be a metal oxide layer, like the first base layer of FIG. 2. However, an impurity is distributed in the second base layer 64 as an element affecting resistance of the storage node S1. Here, the impurity may be silicon (Si), for example. The concentration of silicon distributed in the second base layer 64 may be from 0 to about 0.2. The second oxygen exchange layer 66 may be a metal oxide layer. No silicon is distributed in the second oxygen exchange layer 66.

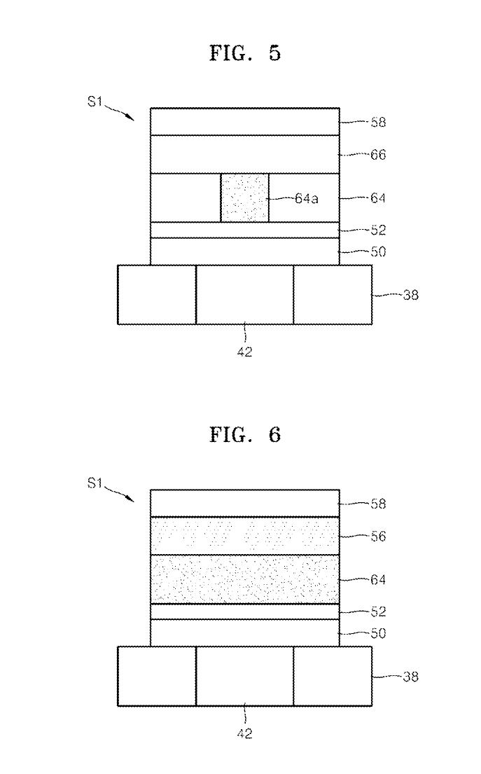

FIG. 5 shows that silicon is distributed only in a portion of a base layer in the storage node of FIG. 4.

Referring to FIG. 5, a silicon distribution in the second base layer 64 may be limited to a portion 64a of the second base layer 64. Therefore, as in the example embodiments shown in FIG. 3, a current path may be limited in the example embodiments shown in FIG. 5. In other words, a current path between the first and second electrodes 50 and 58 in FIG. 5 may be formed only via the portion 64a of the second base layer 64.

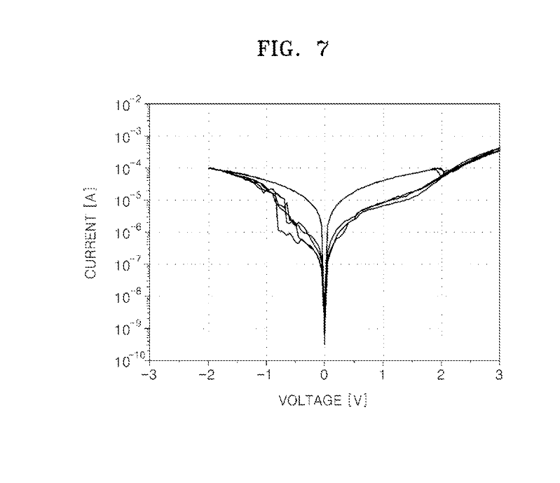

FIG. 6 shows another example of the storage node of FIG. 1.

Referring to FIG. 6, the storage node S1 includes the first electrode 50, the buffer layer 52, the second base layer 64, the first oxygen exchange layer 56, and the second electrode 58 that are stacked in the order stated. Because the components of the storage node S1 shown in FIG. 6 are described above, detailed descriptions thereof will be omitted. However, considering the example embodiments shown in FIGS. 3 and 5, silicon distributions in the second base layer 64 and the first oxygen exchange layer 56 may be limited to portions of the second base layer 64 and the first oxygen exchange layer 56, respectively.

Oxygen reactivity of the first oxygen exchange layer 56 and/or the second base layer 64 may be controlled by the impurity added to the first oxygen exchange layer 56 and/or the second base layer 64. Therefore, current (I)-voltage (V) characteristics of the storage node S1 may differ from that of the storage node S1 in the related art in which the first oxygen exchange layer 56 and the second base layer 64 are not doped with the impurity. Detailed description thereof will be given below with reference to FIGS. 7 through 9.

FIGS. 7 through 9 show experimental results of current-voltage characteristics of the storage node with the configuration in the related art and the storage node with the configuration according to example embodiments.

FIG. 7 shows current-voltage characteristics of a storage node S1 in a case where the storage node S1 has the configuration in the related art (both an oxygen exchange layer and a base layer of the storage node S1 do not contain an impurity) (referred to hereinafter as a first case).

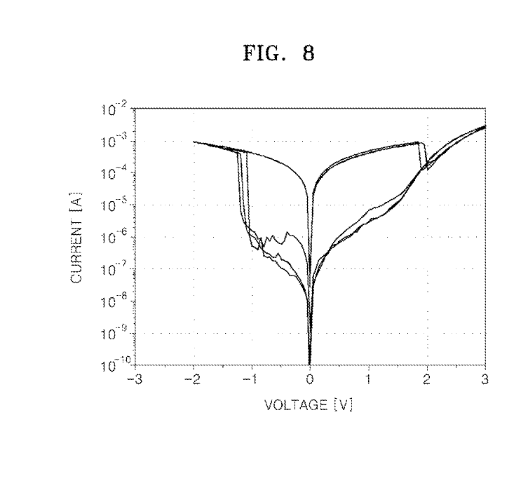

FIG. 8 shows current-voltage characteristics of a storage node S1 in a case where configuration of the storage node S1 differs from the configuration in the related art (both the second base layer 64 and the first oxygen exchange layer 56 of the storage node S1 contain silicon as an impurity) as shown in FIG. 6. (referred to hereinafter as a second case).

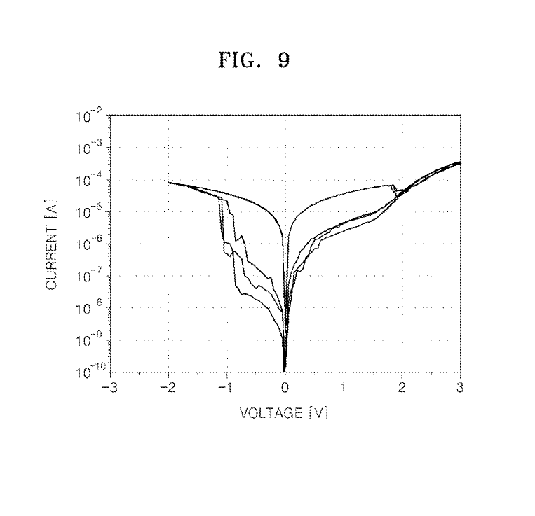

FIG. 9 shows current-voltage characteristics of the storage node S1 in a case where configuration of the storage node S1 differs from the configuration in the related art (silicon is distributed only in the oxygen exchange layer 56 as an impurity) as shown in FIG. 2 or 3 (referred to hereinafter as a third case).

In the experiments for acquiring the results shown in FIGS. 7 through 9, a Ta₂O₅ layer is used as the first oxygen exchange layer 56, whereas an oxygen-rich TaOₓ layer is used as the second base layer 64. Furthermore, the silicon concentration of the first oxygen exchange layer 56 is from 0 to about 0.2. Furthermore, the silicon concentration of second base layer 64 is from 0 to about 0.2.

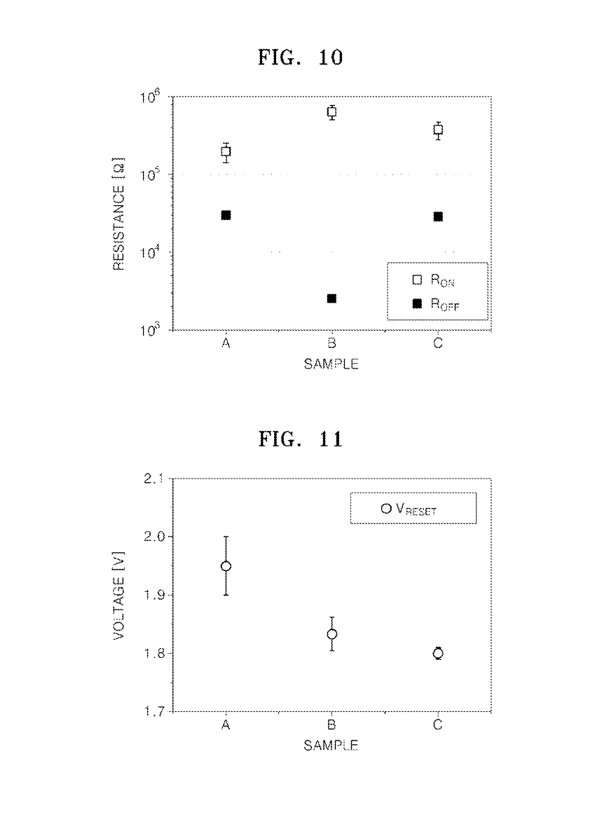

FIGS. 10 and 11 show data values extracted from FIGS. 7 through 9.

FIG. 10 shows changes of high resistance R_{off} and low resistance Rₒₙ respectively in the first through third cases.

FIG. 11 shows changes of reset voltage Vᵣₑₛₑₜ respectively in the first through third cases.

Referring to FIG. 10, values of the low resistance Rₒₙ in the second and third cases are lower than value of the low resistance Rₒₙ in the first case. Furthermore, values of the high resistance R_{off} in the second and third cases are greater than value of the high resistance R_{off} in the first case. Furthermore, differences between the high resistance R_{off} and the low resistance Rₒₙ decrease in the order of the second case, the third case, and the first case. The result shows that a reading margin of the memory device shown in FIG. 1 is greater than that of a memory device in the related art. Therefore, it is clear that reliability of reading operation of the memory device shown in FIG. 1 is higher than that of a memory device in the related art.

Referring to FIG. 11, reset voltages decrease in the order of the first case, the second case, and the third case. As shown in FIG. 11, it is clear that reset voltage of the memory device shown in FIG. 1 may be lower than that of a memory device in the related art.

The reset current Iᵣₑₛₑₜ is defined as the maximum current which flows when the reset voltage Vᵣₑₛₑₜ is applied and may be expressed as Iᵣₑₛₑₜ=Vᵣₑₛₑₜ/Rₒₙ. Therefore, when the reset voltage Vᵣₑₛₑₜ decreases and the low resistance Rₒₙ increases, the reset current Iᵣₑₛₑₜ decreases.

Referring to FIGS. 10 and 11, a case in which the reset voltage Vᵣₑₛₑₜ is lower than that of the memory device in the related art corresponds to the second and third cases in which silicon is distributed in the oxygen exchange layer. When the reset voltage Vᵣₑₛₑₜ is low, the reset current Iᵣₑₛₑₜ may be lower than that of the memory device in the related art even if the low resistance Rₒₙ is same as that of the memory device in the related art. In the third case, the low resistance Rₒₙ is same as or similar to that of the memory device in the related art. Therefore, in a memory device according to example embodiments, not only the reset voltage Vᵣₑₛₑₜ, but also the reset current Iᵣₑₛₑₜ may be reduced, and thus power consumption of the memory device may be reduced.

Furthermore, as shown in FIGS. 8, 9, and 10, in the second and third cases, a difference between the low resistance Rₒₙ and the high resistance R_{off} is greater than that in the first case (the related art), ON/OFF resistance ratio of a memory device may be improved. Therefore, a sufficient resistance ratio for embodying multi-bits and a sufficient margin for reading data may be secured. As a result, data may be read more precisely, and thus reliability of data reading operation may be improved.

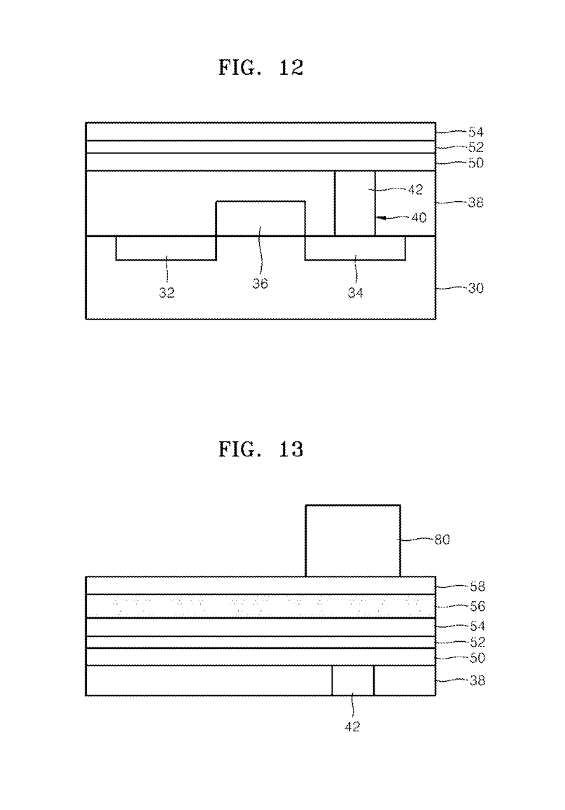

Next, a method of manufacturing a RRAM device according to example embodiments will be described with reference to FIGS. 12 through 14. Here, components identical to the components described above will be denoted by the same reference numerals and detailed descriptions thereof will be omitted.

Referring to FIG. 12, the gate stack 36 is formed on a set portion of the substrate 30. The first and second impurity regions 32 and 34 are formed by ion-implanting a conductive impurity to portions of the substrate 30 around the gate stack 36. The conductive impurity may be an impurity of a conductive type opposite to the impurity implanted to the substrate 30, and may be an n-type or p-type impurity. The first and second impurity regions 32 and 34 and the gate stack 36 may form a transistor. The interlayer insulation layer 38 is formed on the substrate 30 to cover the transistor. The interlayer insulation layer 38 may be formed of a common insulation material. The contact hole 40 for exposing the second impurity region 34 is formed in the interlayer insulation layer 38. The contact hole 40 is filled with the conductive plug 42. The first electrode 50 is formed on the interlayer insulation layer 38 to cover the conductive plug 42. The buffer layer 52 and the first base layer 54 are formed on the first electrode 50 in the order stated.

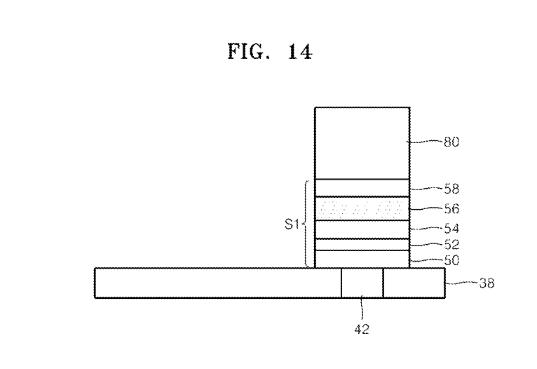

Next, referring to FIG. 13, the first oxygen exchange layer 56 and the second electrode 58 are formed on the first base layer 54 in the order stated. When the first oxygen exchange layer 56 is formed, an impurity (e.g., silicon) may be added thereto. Silicon may be either added during formation of the first oxygen exchange layer 56 or implanted to the first oxygen exchange layer 56 after the first oxygen exchange layer 56 is formed. After the second electrode 58 is formed, a mask 80 is formed on a portion of the second electrode 58. The mask 80 may be a photosensitive film, for example. The mask 80 defines a region in which the storage node 51 of FIG. 1 is to be formed. After the mask 80 is formed, the second electrode 58, the first oxygen exchange layer 56, the first base layer 54, the buffer layer 52, and the first electrode 50 around the mask 80 are etched in the order stated. The etching is performed until the top surface of the interlayer insulation layer 38 is exposed. As a result, as shown in FIG. 14, the storage node 51 including the first electrode 50, the buffer layer 52, the first base layer 54, the first oxygen exchange layer 56, and the second electrode 58 that are stacked on the interlayer insulation layer 38 in the order stated is formed. Next, the mask 80 is removed.

Meanwhile, when the first base layer 54 is formed during the manufacturing operation shown in FIG. 12, silicon may be added as an impurity used as an element, for example. Here, silicon may be added during formation of the first base layer 54, or may be implanted to the first base layer 54 after the first base layer 54 is formed. In a case where silicon is added to the first base layer 54, silicon may be, or may not be, added to the first oxygen exchange layer 56.

As described above, in a RRAM device according to example embodiments, a metal oxide layer of a storage node, which is a data storage unit, contains a desired impurity. The impurity affects resistance of the metal oxide layer, thus being an element affecting resistance of the storage node. Due to the element, high resistance of the storage node may become higher than that in the related art, whereas low resistance of the storage node may be equal to or may become lower than that in the related art. Therefore, reset voltage Vᵣₑₛₑₜ of the RRAM device becomes lower than that in the related art, and thus operating voltage and reset current of the RRAM device may be reduced. As a result, power consumption of the RRAM device may be reduced. Furthermore, because ON/OFF resistance ratio of the RRAM device increases, a multi-bit memory device may be embodied.

It should be understood that the example embodiments described therein should be considered in a descriptive sense only and not for purposes of limitation. Descriptions of features or aspects within each example embodiment should typically be considered as available for other similar features or aspects in other example embodiments.

What is claimed is:

1. A resistive random access memory (RRAM) device, comprising:
a switching device; and
a storage node connected to the switching device,
wherein the storage node includes a first electrode, a metal oxide layer, and a second electrode sequentially stacked, and
the metal oxide layer contains a semiconductor material element affecting resistance of the storage node.

2. The RRAM device of claim 1, wherein the metal oxide layer includes a base layer and an oxygen exchange layer sequentially stacked.

3. The RRAM device of claim 2, wherein at least one of the base layer and the oxygen exchange layer contains the semiconductor material element.

4. The RRAM device of claim 2, wherein the base layer is a nonstoichiometric TaOₓ layer.

5. The RRAM device of claim 2, wherein the oxygen exchange layer is a Ta₂O₅ layer.

6. The RRAM device of claim 1, wherein the semiconductor material element is distributed throughout the metal oxide layer or in a portion of the metal oxide layer.

7. The RRAM device of claim 1, further comprising:
a buffer layer between the first electrode and the metal oxide layer.

8. The RRAM device of claim 1, wherein the semiconductor material element is silicon (Si).

9. A method of manufacturing a resistive random access memory (RRAM) device, the method comprising:
forming a switching device on a substrate; and
forming a storage node connected to the switching device by sequentially forming a first electrode, a metal oxide layer and a second electrode,
wherein a semiconductor material element affecting resistance of the storage node is added to the metal oxide layer.

10. The method of claim 9, further comprising:
forming a buffer layer between the first electrode and the metal oxide layer.

11. The method of claim 9, wherein the semiconductor material element is added to the metal oxide layer, when forming the metal oxide layer.

12. The method of claim 9, wherein the semiconductor material element is implanted to the metal oxide layer, after forming the metal oxide layer.

13. The method of claim 9, wherein the semiconductor material element is silicon (Si).

14. The method of claim 9, wherein the semiconductor material element is distributed throughout the metal oxide layer or in a portion of the metal oxide layer.

15. The method of claim 9, wherein forming the metal oxide layer includes,
forming a base layer on the first electrode; and
forming an oxygen exchange layer on the base layer.

16. The method of claim 15, wherein the semiconductor material element is added to at least one of the base layer and the oxygen exchange layer.

17. The method of claim 15, wherein the base layer is a nonstoichiometric TaOₓ layer.

18. The method of claim 15, wherein the oxygen exchange layer is a Ta₂O₅ layer.
